(19) United States
(12) Patent Application Publication
(10) Pub. No.: US 2014/0361175 A1
(43) Pub. Date: Dec. 11, 2014

(54) DEVICE FOR EXTRACTING DEPTH INFORMATION USING INFRARED LIGHT AND METHOD THEREOF

(71) Applicant: KOREA INSTITUTE OF SCIENCE AND TECHNOLOGY, Seoul (KR)

(72) Inventors: Hwasup Lim, Seoul (KR); Jae Hun Kim, Busan (KR); Sang Chul Ahn, Seoul (KR); Hyoung Gon Kim, Seoul (KR); Junha Roh, Seoul (KR)

(73) Assignee: KOREA INSTITUTE OF SCIENCE AND TECHNOLOGY, Seoul (KR)

(21) Appl. No.: 14/067,028

(22) Filed: Oct. 30, 2013

(30) Foreign Application Priority Data
Jun. 7, 2013 (KR) 10-2013-0065412
Sep. 23, 2013 (KR) 10-2013-0112467

(51) Int. Cl. G01B 11/22; G01J 5/08

(52) U.S. Cl. CPC G01B 11/22; G01J 5/0803
USPC 250/341.8; 250/338.1

(57) ABSTRACT

Disclosed is a device for extracting depth information using infrared light which can be provided at low cost in such a way to apply a nonlinear crystal and a photonic crystal to a depth camera and comprises infrared light emission unit which emits a first infrared light toward a subject; a wavelength conversion unit which concerts the first infrared light reflected from the subject into a second infrared light having a wavelength shorter than the wavelength of the first infrared light; and depth information extraction unit which detects the converted second infrared light and extracts depth information of the subject, wherein the wavelength conversion unit is formed of a crystal capable of concerting the length of the wavelength. The wavelength conversion unit is formed of a crystal which is capable of converting the length of wavelength.

### CROSS-REFERENCE TO RELATED APPLICATION

This application claims priority to Korean Patent Application No. 10-2013-0065412 filed on Jun. 7, 2013 and No. 10-2013-0112467 filed on Sep. 23, 2013 and all the benefits accruing therefrom under 35 U.S.C. §119, the contents of which in its entirety are herein incorporated by reference.

### BACKGROUND

1. Field

The present invention relates to a device for extracting depth information using infrared light and a method thereof, and in particular to a device for extracting depth information using infrared light and a method thereof which make it possible to extract depth information of a certain subject for photographing using infrared light in an outdoor area.

2. Discussion of the Background

Along with the increasing interests on a three-dimensional image display and a three-dimensional image recognition technology, many researches are in progress on the developments of a depth camera. The depth camera is generally classified into an universal type indoor depth camera and a special type outdoor depth camera, of which the universal type indoor depth camera uses a CMOS (Complementary Metal-Oxide Semiconductor) sensor and is configured to emit infrared light of a bandwidth of 800 nm and to measure a distance using a structured light-based triangulation method or a TOF (Time Of Flight) method.

FIG. 1 is a view illustrating a conventional photoelectric efficiency of a conventional CMOS sensor. The CMOS sensor can be used in a range of 400 nm which corresponds to a visible light and 1000 nm which corresponds to infrared light and can be manufactured at low cost. The conventional depth camera mainly uses infrared light of 750-800 nm where shows a good photoelectric efficiency in a CMOS sensor.

FIG. 2 is a view illustrating a spectrum of sunlight which reaches the ground. The sunlight which reaches the ground contains an intensified infrared light of a bandwidth of 750-800 nm. If the universal type indoor depth camera is used in an outdoor area, more infrared light of sunlight are inputted into the depth camera as compared to the infrared ray that the depth camera has emitted, so it is impossible to measure an accurate depth value of a certain subject, for which the universal type indoor depth camera cannot be used in an outdoor area where sunlight is present.

The special type outdoor depth camera is exclusively designed to utilize infrared light of a bandwidth of 1350-1400 nm, the range of which cannot be defined in sunlight which reaches the ground. The image sensor which is able to recognize the infrared light of the above mentioned bandwidth is made from an expensive material such as GaAs (Gallium Arsenide), not silicon. Since it is not easy to manufacture GaAs through a common CMOS process, the special type outdoor depth camera generally uses another type sensor, not a CMOS sensor. The special type outdoor depth camera sells at a higher price than the universal type indoor depth camera.

Since sunlight contains a lot of infrared light of a bandwidth of 750-800 nm, the depth camera utilizing infrared light of 750-800 nm cannot be used in an outdoor area where sunlight is present. The present invention is basically directed to emitting infrared light of a bandwidth of 1350-1400 nm the range of which is not present in sunlight which reaches the ground, to converting using a nonlinear crystal a wavelength of infrared light which is reflected from a subject or a certain thing, into a bandwidth of 675-700 nm, and to photographing the same using a CMOS image sensor and to measuring a certain depth.

### SUMMARY

Accordingly, it is an object of the present invention to provide a device for extracting depth information using infrared light and a method thereof which make it possible to use a conventional CMOS sensor so as to provide an outdoor depth camera at low price.

It is another object of the present invention to provide a device for extracting depth information using infrared light and a method thereof which make it possible to use a conventional CMOS sensor in such a way to convert infrared light of a bandwidth of 1350-1400 nm the range of which is not present in sunlight which reaches the ground into infrared light of a bandwidth of 675-700 nm.

It is further another object of the present invention to provide a device for extracting depth information using infrared light and a method thereof which make it possible to change the wavelength of infrared light using a crystal during a designing procedure.

To achieve the above objects, there is provided a device for extracting depth information using infrared light, comprising infrared light emission unit which emits a first infrared light toward a subject; a wavelength conversion unit which concerts the first infrared light reflected from the subject into a second infrared light having a wavelength shorter than the wavelength of the first infrared light; and depth information extraction unit which detects the converted second infrared light and extracts depth information of the subject, wherein the wavelength conversion unit is formed of a crystal capable of concerting the length of the wavelength.

In addition, the crystal generates a second infrared light by modulating the light to have half of the length of the wavelength of the inputted first infrared light.

In addition, the first infrared light has a wavelength in a range of 1200 nm to 1600 nm, and the second infrared light has a wavelength in a range of 600 nm to 800 nm.

In addition, the crystal comprises a nonlinear crystal and a photonic crystal.

In addition, the nonlinear crystal is formed of at least one selected from the group consisting of lithium niobate, lithium equilibrated lithium niobate, lithium kalium niobate, lithium iodate, KTP, KTA, barium borate, LBO, periodically poled KTP and lithium niobate.

In addition, the wavelength conversion unit comprises a resonator or a cavity in addition to the nonlinear crystal.

In addition, the photonic crystal is formed of an optical insulator substance including silicon.

In addition, the photonic crystal is formed of at least two difference substances having different dielectric constants.

In addition, the photonic crystal is formed in a three-dimensional lattice structure.

In addition, there is further provided either a first filter unit which receives the light reflected from the subject and filters a first infrared light contained in the reflected light and transfers to the wavelength conversion unit or a second filter unit which receives a light from the wavelength conversion unit and filters a second infrared light contained in the received light and transfer to the depth information extraction unit.

To achieve the above objects, there is provided a method for extracting depth information using infrared light, comprising emitting a first infrared light toward a subject; receiving the first infrared light reflected from the subject and converting into a second infrared light which has a wavelength shorter than the wavelength of the first infrared light; and detecting the converted second infrared light and extracting depth information of the subject, wherein the step for converting the first infrared light into the second infrared light comprises inputting the first infrared light into a crystal which is capable of converting the length of the wavelength and converting into a second infrared light.

In addition, the step for converting the first infrared light into the second infrared light is directed to converting for the length of the wavelength of the second infrared light to be half of the length of the wavelength of the first infrared light.

In addition, the first infrared light has a wavelength in a range of 1200 nm to 1600 nm, and the second infrared light has a wavelength in a range of 600 nm to 800 nm.

In addition, the crystal is formed of either a nonlinear crystal or a photonic crystal.

In addition, the nonlinear crystal is formed of at least one selected from the group consisting of lithium niobate, lithium equilibrated lithium niobate, lithium kalium niobate, lithium iodate, KTP, KTA, barium borate, LBO, periodically poled KTP and lithium niobate.

In addition, the step for converting the first infrared light into the second infrared light is performed in such a way to add a resonator or a cavity to the nonlinear crystal.

In addition, the photonic crystal is formed of an optical insulator substance including silicon.

In addition, the photonic crystal is formed of at least two different substances having different dielectric constants.

In addition, the photonic crystal is formed in a three-dimensional lattice structure.

In addition, there is further provided either receiving the light reflected from the subject and filtering the first infrared light contained in the reflected light before the step for converting the first infrared light into the second infrared light or filtering the second infrared light contained in the converted light including the second infrared light after the step for converting the first infrared light into the second infrared light.

The present invention has features in that the outdoor depth camera can be manufactured at low cost in such a way to use a conventional CMOS sensor by converting using a crystal infrared light of a bandwidth of 1350-1400 nm into infrared light of a bandwidth of 675-700 nm.

### BRIEF DESCRIPTION OF THE DRAWINGS

The present invention will become better understood with reference to the accompanying drawings which are given only by way of illustration and thus are not limitative of the present invention, wherein;

FIG. 1 is a photoelectric efficiency graph of a conventional CMOS sensor;

FIG. 2 is a spectrum graph of sunlight which reaches the ground;

FIG. 3 is a structural view illustrating depth information extraction device according to an embodiment of the present invention;

FIG. 4 is a view illustrating a nonlinear crystal according to an embodiment of the present invention;

FIGS. 5A, 5B and 5C are structural views illustrating a photonic crystal having a one-dimensional structure, a two-dimensional structure and a three-dimensional structure;

FIG. 6 is a structural view illustrating a photonic crystal according to an embodiment of the present invention;

FIG. 7A is a graph showing a waveform detected in a region “a” of FIG. 6; and

FIG. 7B is a graph showing a waveform detected in a region “b” of FIG. 6.

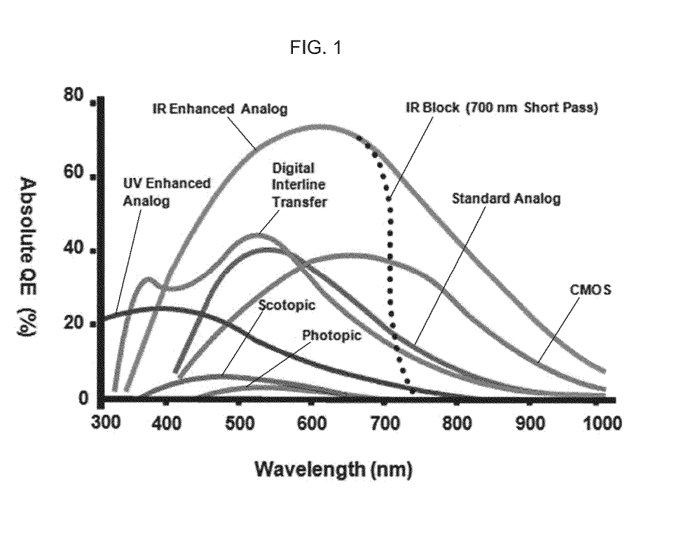

### DETAILED DESCRIPTION OF THE ILLUSTRATED EMBODIMENTS

The device for extracting depth information using infrared light and a method thereof according to the present invention will be described with reference to the accompanying drawings.

It is noted that the same elements are given the same reference numerals throughout the embodiments, and the repeating descriptions thereon will be omitted. It is also noted that the elements shown in the drawings don't exactly match with the actual sizes of them.

A singular form used throughout the descriptions and claims may be interpreted as a plural form unless otherwise stated. The terms such as an ordinal number of a first, a second, etc. used throughout the descriptions and claims may be used to express various elements; however they should be interpreted as ones distinguishing one element from other elements and should not be limited by their own expressions.

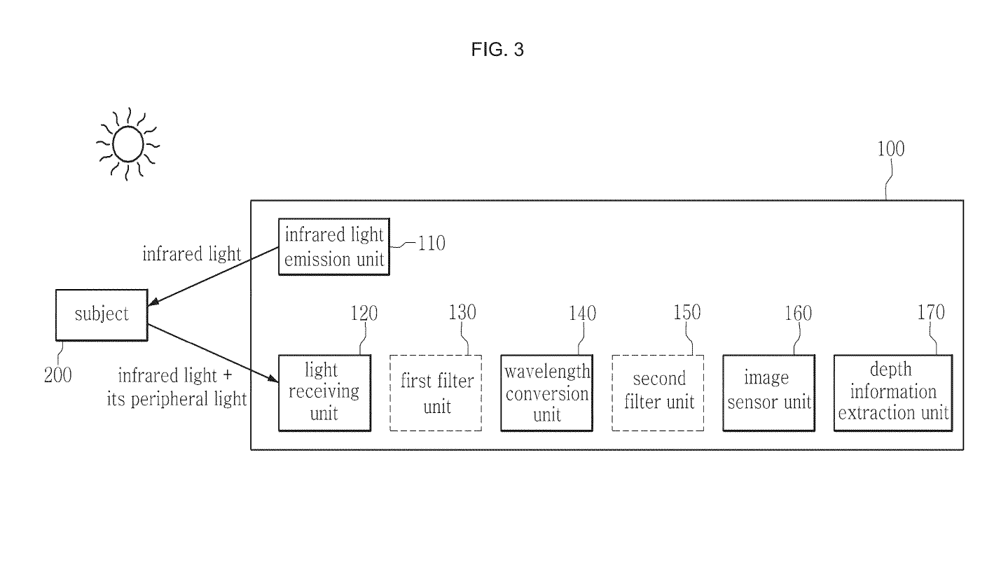

FIG. 3 is a structural view illustrating depth information extraction device 100 according to an embodiment of the present invention.

According to an embodiment of the present invention, the depth information extraction device 100 comprises infrared light emission unit 110, a light receiving unit 120, a first filter unit 130, a wavelength conversion unit 140, a second filter unit 150, an image sensor unit 160 and depth information extraction unit 170.

The infrared light emission unit 110 generates a first infrared light having a first wavelength and emits the first infrared light to a subject 200 the depth image of which will be generated.

The first infrared light has a wavelength bandwidth the intensity of which infrared light usually observed on the surface of the earth under a solar environment is below a first threshold. The first threshold is not fixed at a predetermined value, but is selectively set as a different value. For example, the first threshold may be 0.01 (W/m²/nm).

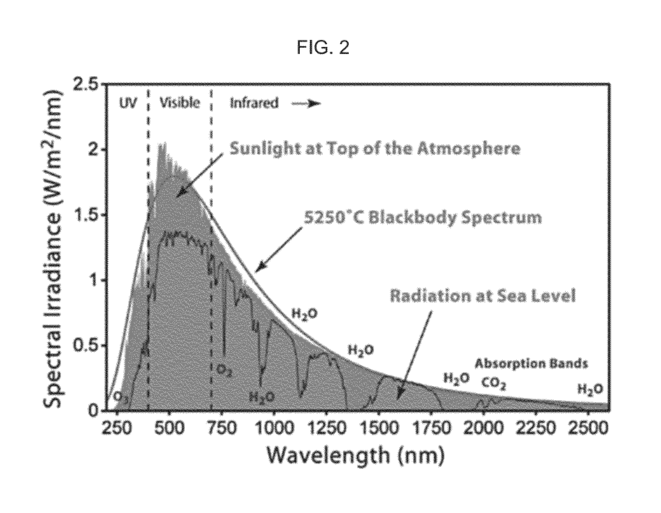

It is known that the sunlight spectrum has different intensities by wavelength. Since the solar radiation is reflected or absorbed by air, vapor, cloud, dusts, etc. in the atmosphere, the intensities of the sunlight spectrum measured on the surface of the earth are different by wavelength. As the intensities of the sunlight spectrum observed on the surface of the earth become much lower, there may be a few wavelength bandwidths which might be zero or might be close to zero. Among the wavelength bandwidths whose spectrum intensities become much lower, as shown in FIG. 2, the infrared light emission unit 110 emits a first infrared light of a wavelength bandwidth of 1200 nm-1600 nm. It is preferred that the infrared light emission unit 110 emits a first infrared light of a wavelength bandwidth of 1350 nm-1400 nm.

The light receiving unit 120 externally receives light. The light inputted into the light receiving unit 120 contains light that the infrared light emission unit 110 emits and is reflected by the subject 200 and its peripheral light.

The wavelength conversion unit 140 generates a wavelength which is half of the length of the inputted wavelength. The wavelength conversion unit 140 converts infrared light (first infrared light) of a wavelength bandwidth of 1200 nm-1600 nm emitted from the infrared light emission unit 110 into infrared light (second infrared light) of a bandwidth of 600-800 nm which can be used by the CMOS sensor. It is preferred that the wavelength conversion unit 140 converts a first infrared light of a wavelength bandwidth of 1350 nm-1400 nm into a second infrared light of a wavelength bandwidth of 775 nm-800 nm. The wavelength conversion unit may be formed of a crystal. The crystal can convert a wavelength of inputted light into a light with another wavelength and emits the converted light. The above mentioned crystal will be described later.

When the light inputted from the light receiving unit 120 is directly used, the infrared light emitted from the infrared light emission unit 110 and its peripheral light are used together, it is impossible to extract an accurate depth information with respect to the subject 200. The depth information extraction unit 100 includes at least one between a first filter unit 130 and a second filter unit 150 so as to remove influence caused by peripheral light. As best seen in FIG. 3, a dotted line indicated for the first filter unit 130 and the second filter unit 150 represents that at least one of the first filter unit 130 and the second filter unit 150 belongs to the depth information extraction device 100 or both belong to the same.

The first filter unit 130 serves to filter a first infrared light (a wavelength bandwidth of 1200 nm-1600 nm, preferably, a wavelength bandwidth of 1350 nm-1400 nm) contained in the light from the light receiving unit 120. Since the wavelength conversion unit 140 is configured to convert only the first infrared light, only the second infrared light is transmitted to the image sensor unit 160.

The second filter unit 150 serves to filter a second infrared light (a wavelength bandwidth of 600 nm-800 nm, preferably, a wavelength bandwidth of 775 nm-800 nm) contained in the light from the wavelength conversion unit 140. If the depth information extraction device 100 is equipped with only a second filter unit 150 without a first filter unit 130, the wavelength conversion unit 140 receive the whole light that the light receiving unit 120 has received. At this time, the wavelength outputted from the wavelength conversion unit 140 corresponds to the light obtained as the second infrared light that the light receiving unit 120 has received and the length of the wavelength of its peripheral light are half converted. The second filter unit 150 filters only the second infrared light and transmits to the image sensor unit 160.

Both the first filter unit 130 and the second filter unit 150 may be provided. In this case, since the filtering processes are performed twice, a peripheral light that the first filter unit 130 might have failed to filter can be filtered again by the second filter unit 150, as a result which it is possible to more accurately extract depth information.

The image sensor unit 160 generates using a second infrared light an electrical signal for each pixel in the image sensor unit 160. The image sensor unit 160 may be formed of a CMOS (Complementary Metal-Oxide Semiconductor) including a silicon-based photodiode. The silicon-based CMOS sensor has a good photoelectric efficiency in a bandwidth of 600-800 nm.

The depth information extraction unit 170 extracts depth information corresponding to the subject 200 with the aid of an electric signal of the image sensor unit 160.

Different from a conventional depth camera, the depth information extraction device 100 according to an embodiment of the present invention is equipped with a wavelength conversion unit 140 and filter units 130 and 150 for thereby improving the problems that the infrared light-based indoor depth cameras which conventionally use a wavelength bandwidth of 600-800 nm cannot be used under an outdoor sunlight environment. As the conventional CMOS sensor can be available for a typical outdoor depth camera, it is possible to manufacture an outdoor depth camera at lower cost than a conventional special type outdoor depth camera.

The depth information extraction device 100 which is available in an outdoor area can be used for the purpose of detecting or recognizing a certain subject which approaches close to a running vehicle or can be used for monitoring an outdoor environment in a three dimension fashion or can be used for photographing a dynamic three-dimensional image in an outdoor area.

The crystal belonging to the wavelength conversion unit 140 according to an embodiment of the present invention will be described in details.

As a crystal which is capable of converting the length of an inputted wavelength and outputting the same, there are a nonlinear crystal and a photonic crystal.

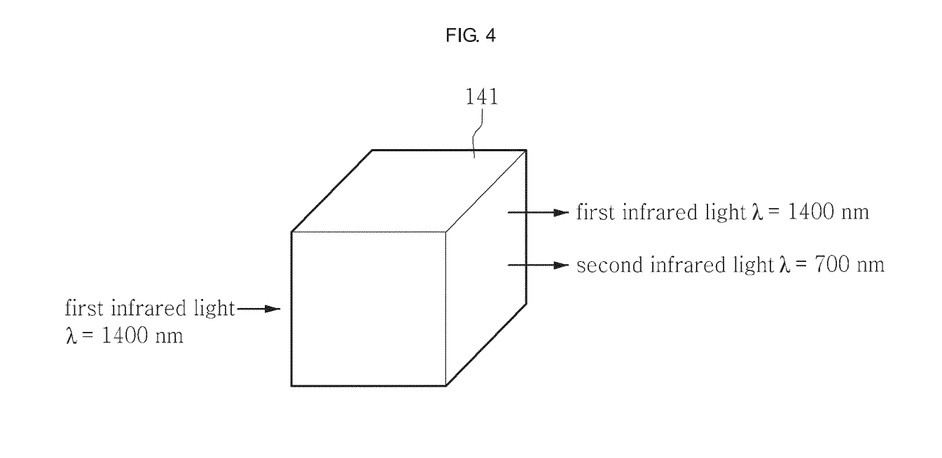

First of all, the nonlinear crystal will be described in details with reference to FIG. 4.

As best seen in FIG. 4, when a first infrared light is inputted, the nonlinear crystal 141 emits a first infrared light and a second infrared light. As for the conversion from the first infrared light into the second infrared light, when the first infrared light is inputted into the nonlinear crystal 141, the optical electrical field causes the electrical dipole moments in the nonlinear crystal 141, and the electrical dipole moments cause a nonlinear polarization in the first infrared light, so the frequency of the first infrared light is converted two times and is outputted. If the frequency becomes double, the length of the wavelength becomes ½, so the second infrared light is outputted.

The nonlinear crystal 141 may be formed of at least one selected from the group consisting of lithium niobate (LiNbO₃), lithium equilibrated lithium niobate, lithium kalium niobate, lithium iodate, KTP, KTA, barium borate, LBO, periodically poled KTP and lithium niobate.

The wavelength conversion unit 140 may be equipped with a resonator or a cavity (for example, a resonant cavity, intracavity, etc.) along with a nonlinear crystal 141 for the sake of the enhanced performance of the nonlinear crystal 141. The resonator or the cavity is helpful to enhance the wavelength conversion efficiency and electric power of the wavelength conversion unit 140. More specifically speaking, if the reflector is placed before and after the nonlinear crystal in the resonator, light repeatedly passes through the nonlinear crystal, so the wavelength conversion efficiency and electric power can be more enhanced.

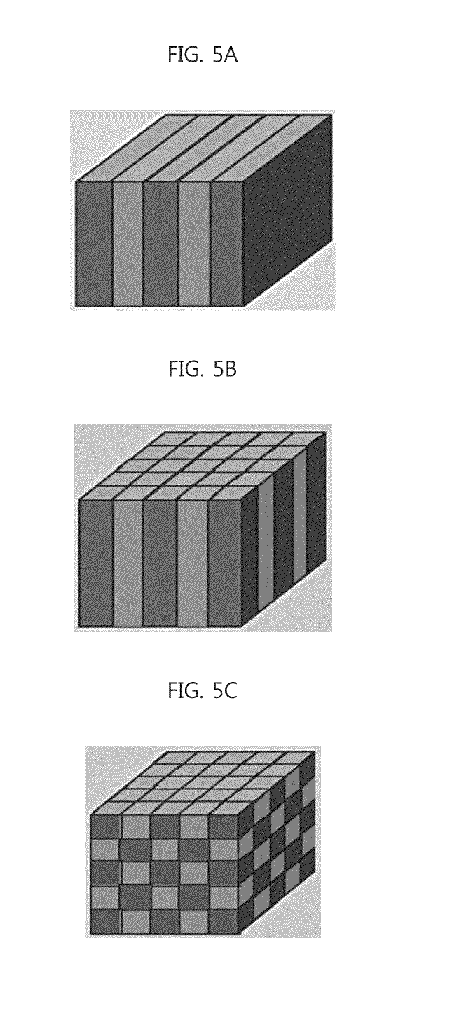

The photonic crystal will be descried in more details with reference to FIGS. 5A to 5C.

The photonic crystal represents an artificial crystal made by periodically arranging dielectrics having different dielectric constants. The substance with a crystal structure has an effect on the propagations of electrons because potentials are periodically produced thanks to a regular arrangement of atoms or molecules, as a result of which a band gap is formed. The above described principle may be identically applied to photon, in which the dielectric plays a role of the potentials with respect to the photon. In this case, a band gap is also formed. To distinguish this band gap from the earlier band gap, it is named a photonic band gap. The photonic band gap may be defined as a certain region where light of a certain wavelength is blocked in view of the transmitivity of light in a wave vector direction of a photonic crystal in a two-dimensional arrangement having different dielectric constants.

The photonic crystal can be formed in three structures.

FIGS. 5A, 5B and 5C are structural views illustrating a photonic crystal having a one-dimensional structure, a two-dimensional structure and a three-dimensional structure;

In case of the photonic crystal of a one-dimensional structure, it can be easily manufactured by periodically stacking different substances (having different dielectric constants or refractive indexes). The properties of a photonic band gap change depending on a direction where each layer is stacked or a stacked structure (for example, the thickness of each layer). The properties of the wavelengths of the photonic crystal can be changed by changing the structure or arrangement of the photonic crystal.

The substance forming the photonic crystal is an optical insulator substance of a lattice structure strongly interacting with light. For example, silicon may be the substance.

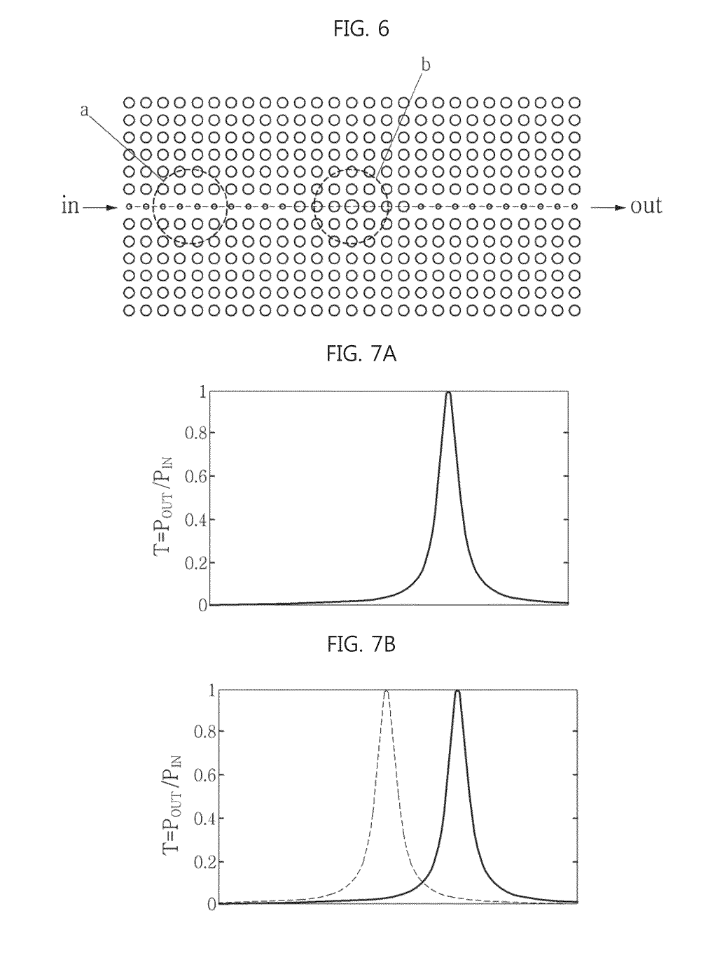

Referring to FIGS. 6, 7A and 7B, the principle that the photonic crystal converts wavelengths will be described.

As best seen in FIG. 6, the light passing through the interior of the photonic crystal has features in that if the lattice arrangement (for example, the interval between the lattices) is similar with the length of the wavelength, the wavelength is not spread or diffracted, but advances straight in one direction. The dotted line of FIG. 6 represents a path along which light advances. The region “a” represents a region where light advances straight in the photonic crystal having a uniform lattice arrangement. If the lattice arrangement changes on the path where the light advances straight, the properties of the light passing through the region may change depending on the changed lattice arrangement, so the length of the wavelength of the light comes to change. The region “b” is a region having a changed lattice arrangement and is where the wavelength of the inputted light is converted.

The frequency of the light detected in the region “a” is shown in FIG. 7A, and the frequency of the light detected in the region “b” is shown in FIG. 7B. More specifically speaking, there exists one more light the frequency of which is changed besides the inputted light. In this state, if the lattice arrangement is changed, the property of the photonic band gap of the region also changes, by which the frequency changes. In order obtain a desired frequency, the lattice should be arranged under the given condition. According to a preferred embodiment of the present invention, when it needs to obtain a wavelength which is half of the length of the inputted wavelength, the lattice should be arranged under the given condition.

In the conventional laser device field, the nonlinear crystal and the photonic crystal are generally used for the sakes of an optical characteristic stabilization of a laser, an output power conversion and control of a laser, etc. In case of the depth information extraction field for a depth camera, as the principle of the depth information extraction, the triangulation method (which is directed to computing the position of a certain point using a distance between the remaining two points and their positions) or a TOF (Time Of Flight) method (which is directed to computing a distance by measuring a time difference while the reference pulse is reflected by a subject and is received after a reference pulse is outputted) are used. Both the indoor depth camera and the outdoor depth camera are adapting a method of directly extracting depth information without converting the light emitted from the depth camera. Since the light is only used as an assistant means when measuring a distance between two points, and it does not need to convert the frequency or intensity of the light, the nonlinear crystal and the photonic crystal have been actually applied in the depth information extraction fields. The preferred embodiments of the present invention are basically directed to providing an outdoor depth camera at low cost in such a way to apply the above mentioned nonlinear crystal and photonic crystal to the depth cameras.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims.

Therefore all changes and modifications that fall within the meets and bounds of the claims, or equivalences of such meets and bounds are therefore intended to be embraced by the appended claims.

What is claimed is:

1. A device for extracting depth information using infrared light, comprising:
infrared light emission unit emitting a first infrared light toward an object;
a wavelength conversion unit converting the first infrared light reflected from the object into a second infrared light having a wavelength shorter than the wavelength of the first infrared light; and
depth information extraction unit detecting the converted second infrared light and extracting depth information of the subject,
wherein the wavelength conversion unit is formed of a crystal capable of concerting the length of the wavelength.

2. The device of claim 1, wherein the crystal generates a second infrared light by modulating the light to have half of the length of the wavelength of the inputted first infrared light.

3. The device of claim 1, wherein the first infrared light has a wavelength in a range of 1200 nm to 1600 nm, and the second infrared light has a wavelength in a range of 600 nm to 800 nm.

4. The device of claim 1, wherein the crystal comprises a nonlinear crystal and a photonic crystal.

5. The device of claim 4, wherein the nonlinear crystal is formed of at least one selected from the group consisting of lithium niobate, lithium equilibrated lithium niobate, lithium kalium niobate, lithium iodate, KTP, KTA, barium borate, LBO, periodically poled KTP and lithium niobate.

6. The device of claim 4, wherein the wavelength conversion unit comprises a resonator or a cavity in addition to the nonlinear crystal.

7. The device of claim 4, wherein the photonic crystal is formed of an optical insulator substance including silicon.

8. The device of claim 4, wherein the photonic crystal is formed of at least two different substances having different dielectric constants.

9. The device of claim 4, wherein the photonic crystal is formed in a three-dimensional lattice structure.

10. The device of claim 1, further comprising either,
a first filter unit receiving the light reflected from the object and filtering a first infrared light contained in the reflected light and transferring to the wavelength conversion unit; or
a second filter unit receiving a light from the wavelength conversion unit and filtering a second infrared light contained in the received light and transferring to the depth information extraction unit.

11. A method for extracting depth information using infrared light, comprising:
emitting a first infrared light toward an object;
receiving the first infrared light reflected from the object and converting into a second infrared light which has a wavelength shorter than the wavelength of the first infrared light; and
detecting the converted second infrared light and extracting depth information of the object,
wherein the step of converting the first infrared light into the second infrared light comprises inputting the first infrared light into a crystal which is capable of converting the length of the wavelength and converting into a second infrared light.

12. The method of claim 11, wherein the step of converting the first infrared light into the second infrared light is directed to converting for the length of the wavelength of the second infrared light to be half of the length of the wavelength of the first infrared light.

13. The method of claim 11, wherein the first infrared light has a wavelength in a range of 1200 nm to 1600 nm, and the second infrared light has a wavelength in a range of 600 nm to 800 nm.

14. The method of claim 11, wherein the crystal is formed of either a nonlinear crystal or a photonic crystal.

15. The method of claim 14, wherein the nonlinear crystal is formed of at least one selected from the group consisting of lithium niobate, lithium equilibrated lithium niobate, lithium kalium niobate, lithium iodate, KTP, KTA, barium borate, LBO, periodically poled KTP and lithium niobate.

16. The method of claim 14, wherein the step of converting the first infrared light into the second infrared light is performed in such a way to add a resonator or a cavity to the nonlinear crystal.

17. The method of claim 14, wherein the photonic crystal is formed of an optical insulator substance including silicon.

18. The method of claim 14, wherein the photonic crystal is formed of at least two different substances having different dielectric constants.

19. The method of claim 14, wherein the photonic crystal is formed in a three-dimensional lattice structure.

20. The method of claim 11, further comprising either,
receiving the light reflected from the subject and filtering the first infrared light contained in the reflected light before the step for converting the first infrared light into the second infrared light; or
filtering the second infrared light contained in the converted light including the second infrared light after the step for converting the first infrared light into the second infrared light.
